(19) United States
(12) Patent Application Publication
(10) Pub. No.: US 2011/0163994 A1
(43) Pub. Date: Jul. 7, 2011

(54) TOUCH SENSING SYSTEM, CAPACITANCE SENSING APPARATUS AND CAPACITANCE SENSING METHOD THEREOF

(75) Inventors: Wing-Kai Tang, Hsinchu City (TW); Ching-Chun Lin, Taipei County (TW); Ching-Ho Hung, Hsinchu City (TW); Tsen-Wei Chang, Taichung County (TW); Yi-Liang Lin, Hsinchu County (TW); Jiun-Jie Tsai, Hsinchu City (TW)

(73) Assignee: NOVATEK MICROELECTRONICS CORP., Hsinchu (TW)

(21) Appl. No.: 12/980,343

(22) Filed: Dec. 29, 2010

(30) Foreign Application Priority Data
Jan. 7, 2010 (TW) 99100234

(51) Int. Cl. G06F 3/044; G01R 27/26

(52) U.S. Cl. 345/174; 324/686

(57) ABSTRACT

A touch sensing system includes a touch input interface and at least one capacitance sensing apparatus. The capacitance sensing apparatus includes a plurality of switch units and a differential sensing circuit. Each of the switch units is coupled to a corresponding sensing capacitor. A sensing input end of the differential sensing circuit receives a capacitance under test provided by at least one of the sensing capacitors. A reference input end of the differential sensing circuit receives a reference capacitance provided by at least one of the sensing capacitors. The differential sensing circuit compares the capacitance under test and the reference capacitance to output a first difference between the capacitance under test and the reference capacitance through an output end of the differential sensing circuit. A capacitance sensing method is also provided.

### CROSS-REFERENCE TO RELATED APPLICATION

This application claims the priority benefit of Taiwan application serial no. 99100234, filed on Jan. 7, 2010. The entirety of the above-mentioned patent application is hereby incorporated by reference herein and made a part of this specification.

### BACKGROUND OF THE INVENTION

1. Field of the Invention

The invention relates to a sensing apparatus and a sensing method. More particularly, the invention relates to a capacitance sensing apparatus and a capacitance sensing method.

2. Description of Related Art

In this information era, reliance on electronic products is increasing day by day. The electronic products including notebook computers, mobile phones, personal digital assistants (PDAs), digital walkmans, and so on are indispensable in our daily lives. Each of the aforesaid electronic products has an input interface for a user to input his or her command, such that an internal system of each of the electronic product spontaneously runs the command. At this current stage, the most common input interface includes a keyboard and a mouse.

From the user's aspect, it is sometimes rather inconvenient to use the conventional input interface including the keyboard and the mouse. Manufacturers aiming to resolve said issue thus start to equip the electronic products with touch input interfaces, e.g. touch pads or touch panels, so as to replace the conditional keyboards and mice. At present, the users' commands are frequently given to the electronic products by physical contact or sensing relationship between users' fingers or styluses and the touch input interfaces. For instance, a capacitive touch input interface characterized by a multi-touch sensing function is more user-friendly than the conventional input interface and thus gradually becomes more and more popular.

However, given that the capacitive touch input interface is applied to a one-end sensing circuit, capacitance of a capacitor under test is required to be measured and stored as a base line capacitance before touch sensing. The base line capacitance is subtracted from the capacitance under test which is measured by the one-end sensing circuit, and thereby the capacitance variations of the capacitor under test can be obtained. Meanwhile, a reference capacitance of the capacitor under test measured by the one-end sensing circuit has a fixed value, and therefore a large voltage region for measuring significant capacitance variations is necessary in the sensing circuit, which however sacrifices accuracy of the measurement.

### SUMMARY OF THE INVENTION

The invention is directed to a capacitance sensing apparatus capable of adjusting reference capacitances of capacitors under test, such that measured results are accurate, and that efficiency of measurement is further improved.

The invention is also directed to a touch sensing system capable of adjusting reference capacitances of capacitors under test by means of a capacitance sensing apparatus, such that measured results are accurate, and that efficiency of measurement is further improved.

The invention is also directed to a capacitance sensing method for adjusting measured reference capacitances of capacitors under test, such that measured results are accurate, and that efficiency of measurement is further improved.

In an embodiment of the invention, a capacitance sensing apparatus including a plurality of switch units and a differential sensing circuit is provided. Each of the switch units has a first end, a second end, and a third end. The third end of each of the switch units is coupled to a corresponding sensing capacitor. The differential sensing circuit has a sensing input end, a reference input end, and an output end. The sensing input end of the differential sensing circuit is coupled to the first end of each of the switch units and receives a capacitance under test provided by at least one of the sensing capacitors. The reference input end of the differential sensing circuit is coupled to the second end of each of the switch units and receives a reference capacitance provided by at least one of the sensing capacitors. The differential sensing circuit compares the capacitance under test and the reference capacitance to output a first difference between the capacitance under test and the reference capacitance through the output end of the differential sensing circuit.

In an embodiment of the invention, a touch sensing system including a touch input interface and at least one capacitance sensing apparatus is provided. The touch input interface includes a plurality of sensing capacitors, and the capacitance sensing apparatus includes a plurality of switch units and a differential sensing circuit. Each of the switch units has a first end, a second end, and a third end. The third end of each of the switch units is coupled to a corresponding one of the sensing capacitors. The differential sensing circuit has a sensing input end, a reference input end, and an output end. The sensing input end of the differential sensing circuit is coupled to the first end of each of the switch units and receives a capacitance under test provided by at least one of the sensing capacitors. The reference input end of the differential sensing circuit is coupled to the second end of each of the switch units and receives a reference capacitance provided by at least one of the sensing capacitors. The differential sensing circuit compares the capacitance under test and the reference capacitance to output a first difference between the capacitance under test and the reference capacitance through the output end of the differential sensing circuit.

According to an embodiment of the invention, each of the switch units includes a first switch and a second switch. The first switch has a first end and a second end. The first end of the first switch is coupled to a corresponding one of the sensing capacitors, and the second end of the first switch is coupled to the sensing input end of the differential sensing circuit. The second switch has a first end and a second end. The first end of the second switch is coupled to the first end of the first switch, and the second end of the second switch is coupled to the reference input end of the differential sensing circuit.

According to an embodiment of the invention, the differential sensing circuit includes a first charge-to-voltage converting circuit, a second charge-to-voltage converting circuit, and a difference comparing unit. The first charge-to-voltage converting circuit is coupled to the first end of each of the switch units to receive the capacitance under test, and the first charge-to-voltage converting circuit converts the capacitance under test into a voltage under test. The second charge-to-voltage converting circuit is coupled to the second end of each of the switch units to receive the reference capacitance, and the second charge-to-voltage converting circuit converts the reference capacitance into a reference voltage. The difference comparing unit has a first sensing input end, a second input end, and an output end. The first input end of the difference comparing unit is coupled to the first charge-to-voltage converting circuit to receive the capacitance under test, and the second input end of the difference comparing unit is coupled to the second charge-to-voltage converting circuit to receive the reference capacitance. The difference comparing unit compares the voltage under test and the reference voltage to output the first difference through the output end of the difference comparing unit.

According to an embodiment of the invention, the differential sensing circuit includes a charge polarity reversing circuit, a charge-to-voltage converting circuit, and a difference comparing unit. The charge polarity reversing circuit is coupled to the second end of each of the switch units to receive a reference charge corresponding to the reference capacitance and reverse polarity of the reference charge. The charge-to-voltage converting circuit is coupled to the first end of each of the switch units to receive a charge under test corresponding to the capacitance under test and receive the reference charge of which the polarity is reversed. Polarity of the charge under test is different from the polarity of the reference charge, and a second difference between the charge under test and the reference charge is obtained. The charge-to-voltage converting circuit converts the second difference into the first difference. The difference comparing unit is coupled to the charge-to-voltage converting circuit to receive, amplify, and output the first difference.

According to an embodiment of the invention, the differential sensing circuit includes a charge polarity reversing circuit and a difference comparing unit. The charge polarity reversing circuit is coupled to the first end of each of the switch units to receive a charge under test corresponding to the capacitance under test and reverse polarity of the charge under test. The difference comparing unit is coupled to the second end of each of the switch units to receive a reference charge corresponding to the reference capacitance and receive the charge under test of which the polarity is reversed. The polarity of the charge under test is different from polarity of the reference charge. A second difference between the charge under test and the reference charge is obtained, and the difference comparing unit converts the second difference into the first difference and outputs the first difference.

According to an embodiment of the invention, the differential sensing circuit further includes a charge polarity non-reversing circuit coupled to the difference comparing unit and the second end of each of the switch units.

According to an embodiment of the invention, the differential sensing circuit includes a charge polarity reversing circuit and a difference comparing unit. The charge polarity reversing circuit is coupled to the second end of each of the switch units to receive a reference charge corresponding to the reference capacitance and reverse polarity of the reference charge. The difference comparing unit is coupled to the first end of each of the switch units to receive a charge under test corresponding to the capacitance under test and receive the reference charge of which the polarity is reversed. Polarity of the charge under test is different from the polarity of the reference charge. A second difference between the charge under test and the reference charge is obtained, and the difference comparing unit converts the second difference into the first difference and outputs the first difference.

According to an embodiment of the invention, the differential sensing circuit further includes a charge polarity non-reversing circuit coupled to the difference comparing unit and the first end of each of the switch units.

According to an embodiment of the invention, the differential sensing circuit includes a differential amplifier, a comparator, or an integrator.

In another embodiment of the invention, a capacitance sensing method including following steps is provided. A plurality of switch units and a differential sensing circuit are provided. Each of the switch units is coupled to a corresponding sensing capacitor. A capacitance under test provided by at least one of the sensing capacitors is received, and a reference capacitance provided by at least one of the sensing capacitors is received. The capacitance under test and the reference capacitance are compared to obtain a first difference between the capacitance under test and the reference capacitance.

According to an embodiment of the invention, the capacitance sensing method further includes following steps. After the capacitance under test is received, the capacitance under test is converted into a voltage under test. After the reference capacitance is received, the reference capacitance is converted into a reference voltage.

According to an embodiment of the invention, in the step of comparing the capacitance under test and the reference capacitance, the voltage under test and the reference voltage are compared to obtain the first difference.

According to an embodiment of the invention, in the step of receiving the reference capacitance, a reference charge corresponding to the reference capacitance is received, and polarity of the reference charge is reversed. In the step of receiving the capacitance under test, a charge under test corresponding to the capacitance under test is received. Polarity of the charge under test is different from the polarity of the reference charge.

According to an embodiment of the invention, the capacitance sensing method further includes receiving the charge under test and the reference charge of which the polarity is reversed, so as to obtain a second difference.

According to an embodiment of the invention, in the step of comparing the capacitance under test and the reference capacitance, the second difference is converted into the first difference, such that the first difference between the capacitance under test and the reference capacitance is obtained.

According to an embodiment of the invention, in the step of receiving the reference capacitance, a reference charge corresponding to the reference capacitance is received. In the step of receiving the capacitance under test, a charge under test corresponding to the capacitance under test is received, and polarity of the charge under test is reversed. Here, the polarity of the charge under test is different from polarity of the reference charge.

According to an embodiment of the invention, the capacitance sensing method further includes receiving the reference charge and the charge under test of which the polarity is reversed, so as to obtain a second difference.

According to an embodiment of the invention, in the step of comparing the capacitance under test and the reference capacitance, the second difference is converted into the first difference, such that the first difference between the capacitance under test and the reference capacitance is obtained.

According to an embodiment of the invention, in the step of comparing the capacitance under test and the reference capacitance, the first difference is obtained by a differential amplifier, a comparator, or an integrator.

Based on the above, in the embodiments of the invention, the capacitance sensing apparatus can control the switch units, such that the reference input end of the differential sensing circuit receives the reference capacitance provided by at least one of the sensing capacitors. The reference capacitance acts as a reference for measuring the capacitance under test. Thereby, the capacitance sensing apparatus is capable of adjusting reference capacitances of the capacitors under test, such that measured results are accurate, and that efficiency of measurement is further improved.

It is to be understood that both the foregoing general descriptions and the following detailed embodiments are exemplary and are, together with the accompanying drawings, intended to provide further explanation of technical features and advantages of the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block circuit diagram illustrating a touch sensing system according to an embodiment of the invention.

FIG. 2A is a block circuit diagram illustrating the capacitance sensing apparatus depicted in FIG. 1.

FIG. 2B is a schematic circuit diagram illustrating the switch units depicted in FIG. 2A.

FIG. 3 is a schematic circuit diagram illustrating the capacitance sensing apparatus depicted in FIG. 2A.

FIG. 4 is a schematic circuit diagram illustrating the capacitance sensing apparatus depicted in FIG. 2A.

FIG. 5 is a capacitance distribution diagram illustrating capacitances of sensing capacitors in the capacitance sensing apparatus depicted in FIG. 2A.

FIG. 6 is a schematic circuit diagram illustrating the capacitance sensing apparatus depicted in FIG. 3.

FIG. 7 illustrates a timing diagram when a capacitance sensing apparatus is operated.

FIG. 8 is another schematic circuit diagram illustrating the capacitance sensing apparatus depicted in FIG. 3.

FIG. 9 is a block circuit diagram illustrating a capacitance sensing apparatus according to an embodiment of the invention.

FIG. 10A is a schematic circuit diagram illustrating a capacitance sensing apparatus according to an embodiment of the invention.

FIG. 10B is a schematic circuit diagram illustrating a capacitance sensing apparatus according to another embodiment of the invention.

FIG. 10C illustrates a timing diagram when the capacitance sensing apparatus depicted in FIG. 10B is operated.

FIG. 11 is a schematic circuit diagram illustrating a capacitance sensing apparatus according to an embodiment of the invention.

FIG. 12A is a schematic circuit diagram illustrating a capacitance sensing apparatus according to an embodiment of the invention.

FIG. 12B is a schematic circuit diagram illustrating a capacitance sensing apparatus according to an embodiment of the invention.

FIG. 13 is a flowchart of a capacitance sensing method according to an embodiment of the invention.

### DESCRIPTION OF EMBODIMENTS

In a capacitive touch input interface, capacitance of a sensing capacitor is determined on whether a position of the sensing capacitor correspondingly on the touch input interface is touched. When the position of the sensing capacitor correspondingly on the touch input interface is touched, capacitance variation is induced by the touch object accordingly, such that a capacitance under test is generated by the touch object and the sensing capacitor.

According to the embodiments of the invention, except for the aforesaid capacitance under test, other capacitances of sensing capacitors can serve as reference values for measuring the capacitance under test. Hence, after the capacitance under test and the reference capacitance are compared, the touch position of the touch object correspondingly on the touch input interface can be determined.

In the embodiments provided hereinafter, a touch panel exemplarily acts as the touch input interface, while people having ordinary skill in the art are aware that the touch panel does not pose a limitation on the touch input interface of the invention. Meanwhile, the invention is not limited to the touch input interface. Any input interface capable of sensing capacitance variations does not depart from the protection scope of the invention.

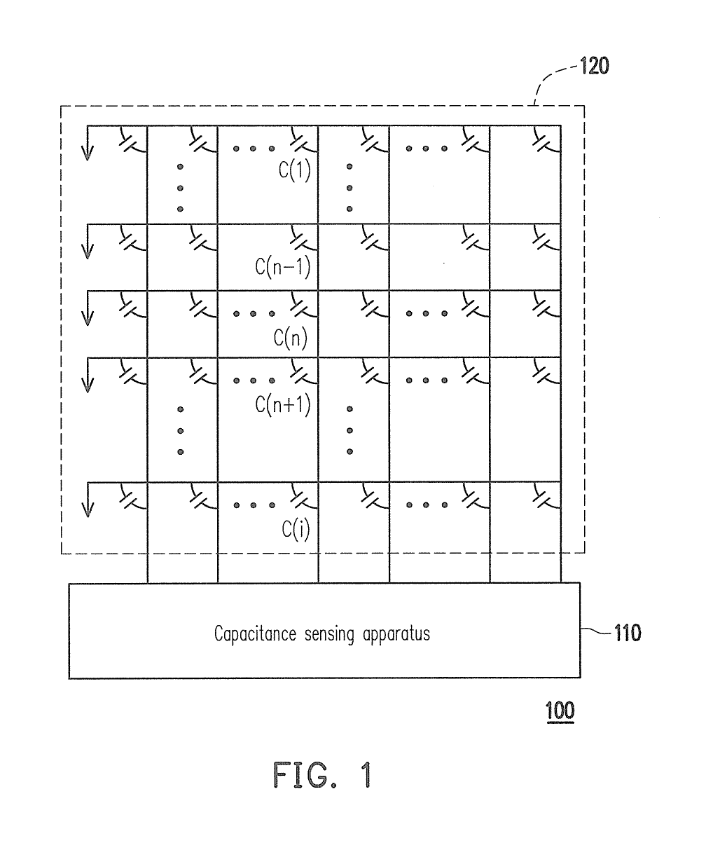

FIG. 1 is a block circuit diagram illustrating a touch sensing system according to an embodiment of the invention. As indicated in FIG. 1, a touch sensing system 100 of this embodiment includes a capacitance sensing apparatus 110 and a touch input interface 120. The touch input interface 120 including a plurality of sensing capacitors is, for example, a touch panel of a display or a touch pad with a touch sensing function.

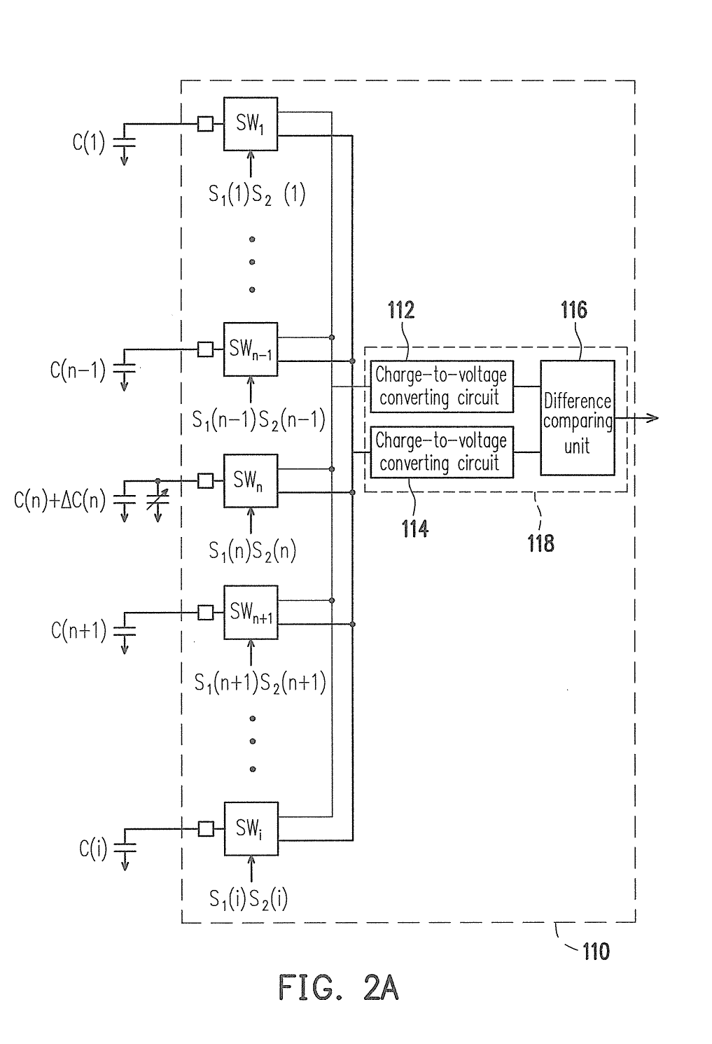

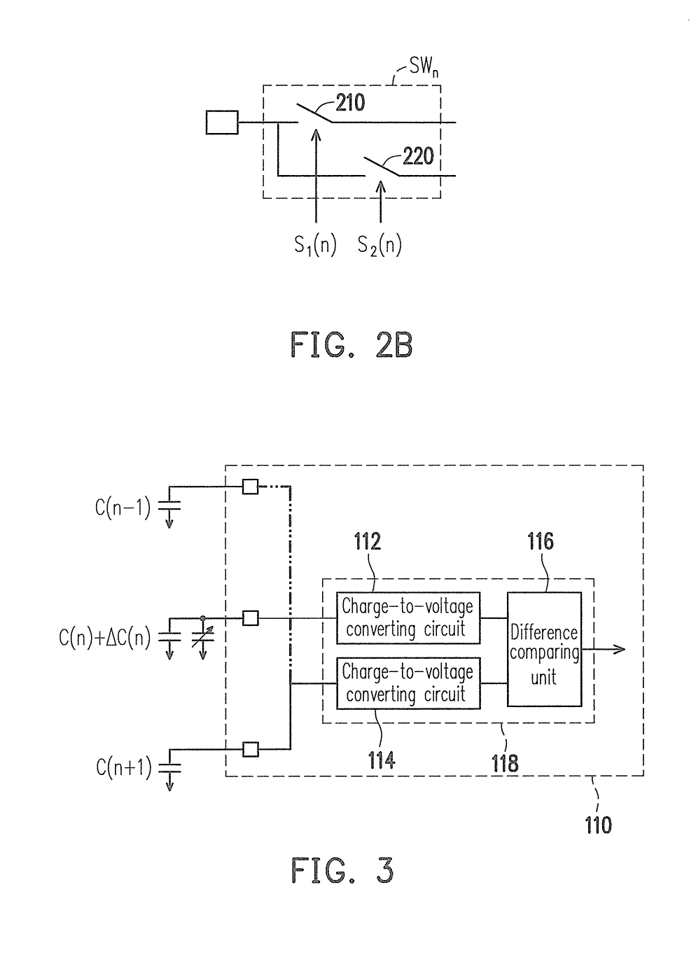

FIG. 2A is a schematic block circuit diagram illustrating the capacitance sensing apparatus 110 depicted in FIG. 1. In FIG. 1 and FIG. 2A, the capacitance sensing apparatus 110 of this embodiment includes a plurality of switch units SW₁, . . . , SWₙ₋₁, SWₙ, SWₙ₊₁, . . . , and SWᵢ and a differential sensing circuit 118. Here, each of the switch units is respectively coupled to a corresponding one of the sensing capacitors C(1)˜C(i) and controlled by a corresponding pair of control signals S₁(1) and S₂(1), . . . , S₁(n−1) and S₂(n−1), S₁(n) and S₂(n), S₁(n+1) and S₂(n+1), . . . , and S₁(i) and S₂(i).

According to this embodiment, capacitances of the sensing capacitors are determined on whether positions of the sensing capacitors correspondingly on the touch input interface are touched. When a position of the exemplary sensing capacitor C(n) correspondingly on the touch input interface is touched, capacitance variation ΔC is induced by the touch object accordingly. Thereby, a capacitance under test C(n)+ΔC is induced by the sensing capacitor C(n) and the capacitance variation ΔC. Through the control of the switch unit SWₙ, the variation of the capacitance under test C(n)+ΔC can be sensed by the differential sensing circuit 118.

Besides, in this embodiment, except for the capacitance under test C(n)+ΔC, other capacitances of the sensing capacitors can serve as reference values for measuring the capacitance under test. For instance, through the switch unit SWₙ₋₁ or SWₙ₊₁, capacitance of the sensing capacitor C(n−1) or C(n+1) can be passed to the differential sensing circuit 118 to serve as a reference capacitance for measuring the capacitance under test C(n)+ΔC, which is however not limited by the embodiment in this invention.

The differential sensing circuit 118 compares the capacitance under test and the reference capacitance to output a first difference between the capacitance under test and the reference capacitance through an output end of the differential sensing circuit 118. In this embodiment, the first difference is, for example, a voltage difference. Based on the first difference, a back-end circuit (not shown) of the capacitance sensing apparatus 110 can determine the touch position on the touch input interface. On the other hand, a touch sensing system of this embodiment is applicable to a self capacitance touch sensing system or a mutual capacitance touch sensing system.

Specifically, FIG. 2B is a schematic circuit diagram illustrating the switch units depicted in FIG. 2A. In FIG. 2B, the switch unit SWₙ serves as an exemplary switch unit, while other switch units can be analogous in this case. In FIG. 2A and FIG. 2B, the switch unit SWₙ of this embodiment includes a first switch 210 and a second switch 220 respectively controlled by the control signal S₁(n) and the control signal S₂(n). In an embodiment, the differential sensing circuit 118 includes charge-to-voltage converting circuits 112 and 114 and a difference comparing unit 116. For instance, the charge-to-voltage converting circuit 112 can act as a sensing input end of the differential sensing circuit 118, and the charge-to-voltage converting circuit 114 can act as a reference input end of the differential sensing circuit 118.

Here, an end of the first switch 210 is coupled to the capacitor under test C(n)+ΔC, and the other end of the first switch 210 is coupled to the charge-to-voltage converting circuit 112 of the differential sensing circuit 118. Besides, an end of the second switch 220 is coupled to the first switch 210, and the other end of the second switch 220 is coupled to the charge-to-voltage converting circuit 114 of the differential sensing circuit 118.

According to this embodiment, when the position of the exemplary sensing capacitor C(n) correspondingly on the touch input interface is touched, the capacitance variation ΔC is induced by the touch object accordingly. Here, the first switch 210 controlled by the control signal S₁(n) is switched on, and the second switch 220 controlled by the control signal S₂(n) is switched off. Hence, the capacitance under test C(n)+ΔC is received by the charge-to-voltage converting circuit 112.

On the other hand, the capacitance of the sensing capacitor C(n+1) can serve as the reference capacitance for measuring the capacitance under test C(n)+ΔC, which is not limited in this invention. Here, the first switch (not shown) of the switch unit SWₙ₊₁ controlled by the control signal S₁(n+1) is switched on, and the second switch (not shown) of the switch unit SWₙ₊₁ controlled by the control signal S₂(n+1) is switched off. Hence, the capacitance of the sensing capacitor C(n+1) is received by the charge-to-voltage converting circuit 114 and considered as the reference capacitance.

In the event that the capacitance of the sensing capacitor serves as the reference capacitance, the capacitance sensing apparatus 110 shown in FIG. 2A can be illustrated in the schematic circuit diagram of FIG. 3. For the purpose of illustration, only the sensing capacitors C(n−1) and C(n+1), the capacitor under test C(n)+ΔC, and the differential sensing circuit 118 are illustrated in FIG. 3, while corresponding switch units are not shown therein.

As indicated in FIG. 3, when the capacitance of the sensing capacitor C(n+1) is taken as the reference capacitance, the charge-to-voltage converting circuit 112 receives the capacitance under test C(n)+ΔC, converts the capacitance under test C(n)+ΔC into a corresponding voltage under test, and transmits the voltage under test to the difference comparing unit 116. In the meantime, the charge-to-voltage converting circuit 114 receives the capacitance of the sensing capacitor C(n+1) as the reference capacitance, converts the reference capacitance into a corresponding reference voltage, and transmits the reference voltage to the difference comparing unit 116.

The difference comparing unit 116 compares the voltage under test and the reference voltage, so as to output the first difference between the capacitance under test and the reference capacitance through an output end of the difference comparing unit 116 and further determine the touch position on the touch input interface. In this embodiment, the first difference is, for example, a voltage difference.

Generally, differences among capacitances of the sensing capacitors on the touch input interface are insignificant. The difference between the capacitance under test C(n)+ΔC and the reference capacitance C(n+1) is ΔC([C(n)+ΔC]-C(n+1)=ΔC).

Namely, when the capacitance of the sensing capacitor C(n+1) is deemed as the reference capacitance, the differential sensing circuit 118 receives the capacitance under test C(n)+ΔC and the reference capacitance C(n+1) respectively through the charge-to-voltage converting circuits 112 and 114, and the difference between the capacitance under test C(n)+ΔC and the reference capacitance C(n+1) is ΔC. The capacitance under test and the reference capacitance are respectively converted into the voltage under test and the reference voltage. The difference comparing unit 116 of the differential sensing circuit 118 compares the voltage under test and the reference voltage to output the voltage difference corresponding to the capacitance difference ΔC.

According to this embodiment, in the capacitance sensing apparatus 110, the capacitance of the sensing capacitor C(n+1) serves as the reference capacitance for measuring the capacitance under test C(n)+ΔC. However, according to other embodiments, the capacitance of the sensing capacitor C(n−1) or capacitance of any other sensing capacitor can also serve as the reference capacitance for measuring the capacitance under test C(n)+ΔC in the capacitor sensing apparatus 110, which is not repetitively described herein. Namely, in the capacitance sensing apparatus 110 of this embodiment, the capacitance of any other sensing capacitor, other than the capacitance under test C(n)+ΔC, can act as the reference capacitance for measuring the capacitance under test C(n)+ΔC.

In another embodiment of the invention, the capacitances of the sensing capacitors C(n+1) and C(n−1) in the capacitance sensing apparatus 110 can both be the reference capacitances for measuring the capacitance under test C(n)+ΔC.

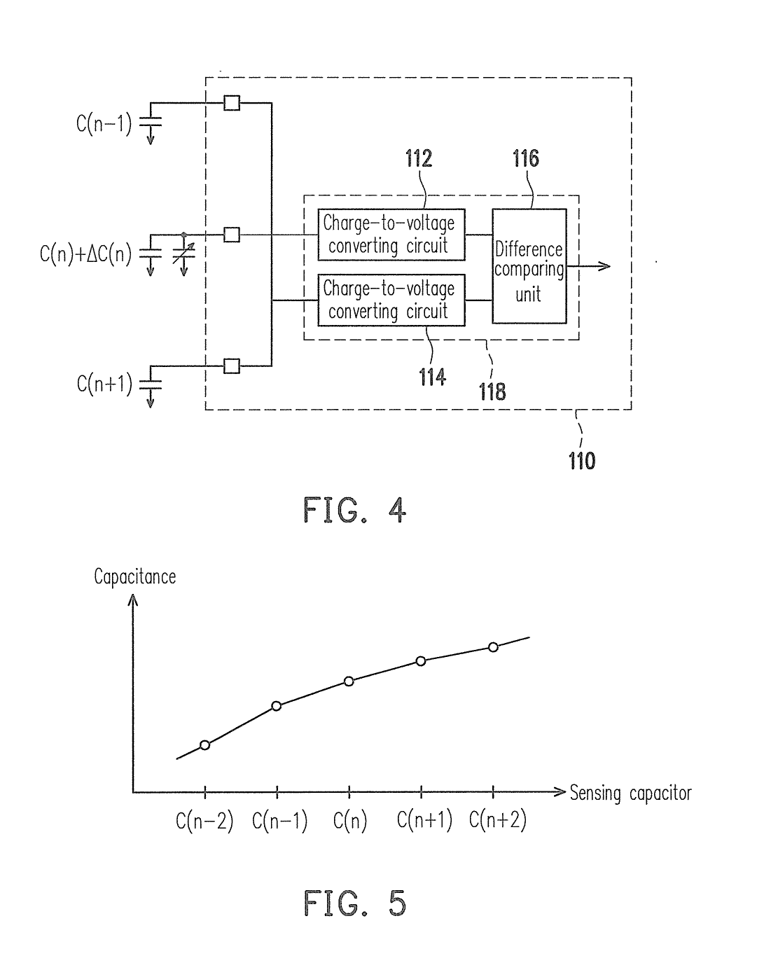

FIG. 4 is a schematic circuit diagram illustrating the capacitance sensing apparatus 110 depicted in FIG. 2A. Here, the capacitances of the sensing capacitors C(n+1) and C(n−1) in the capacitance sensing apparatus 110 both serve as the reference capacitances for measuring the capacitance under test C(n)+ΔC. For the purpose of illustration, only the sensing capacitors C(n−1) and C(n+1), the capacitor under test C(n)+ΔC, and the differential sensing circuit 118 are illustrated in FIG. 4, while corresponding switch units are not shown therein.

FIG. 5 is a distribution diagram illustrating the capacitances of the sensing capacitors in the capacitance sensing apparatus 110 depicted in FIG. 2A. Different manufacturing processes of the sensing capacitors result in varied capacitances. Note that distribution of the capacitances tends to be a one-way, increasing distribution or a one-way, decreasing distribution. According to this embodiment, the capacitances of the sensing capacitors have the one-way, increasing distribution. As indicated in FIG. 5, the capacitance [C(n−1)+C(n+1)]/2 is approximately equal to the capacitance C(n).

With reference to FIG. 4 and FIG. 5, in the capacitance sensing apparatus 110 of this embodiment, the capacitances of the sensing capacitors C(n+1) and C(n−1) both serve as the reference capacitances for measuring the capacitance under test C(n)+ΔC. Hence, the reference capacitance is [C(n−1)+C(n+1)]/2, the capacitance under test is C(n)+ΔC, and the difference therebetween is [C(n)+ΔC]−[C(n−1)+C(n+1)]/2=[C(n)+ΔC]−C(n)=ΔC.

Likewise, the capacitance under test and the reference capacitance are individually converted into the voltage under test and the reference voltage by the charge-to-voltage converting circuits 112 and 114 of the differential sensing circuit 118, respectively. The difference comparing unit 116 of the differential sensing circuit 118 compares the voltage under test and the reference voltage to output the voltage difference corresponding to the capacitance difference ΔC.

Namely, in the capacitance sensing apparatus 110 of this embodiment, the capacitance of any other sensing capacitor, other than the capacitance under test, can act as the reference capacitance for measuring the capacitance under test. In an alternative, the capacitances of the sensing capacitors C(n+1) and C(n−1) can both serve as the reference capacitances for measuring the capacitance under test C(n)+ΔC.

The sensing capacitors C(n+1) and C(n−1) are taken for example in this embodiment, while capacitances of the sensing capacitors C(n+2) and C(n−2) in the capacitance sensing apparatus 110 in other embodiments can both serve as the reference capacitances for measuring the capacitance under test C(n)+ΔC. Alternatively, when there is a capacitance difference ΔC between the capacitance of the sensing capacitor C(n) and any other sensing capacitance, the any other sensing capacitance can act as the reference capacitance.

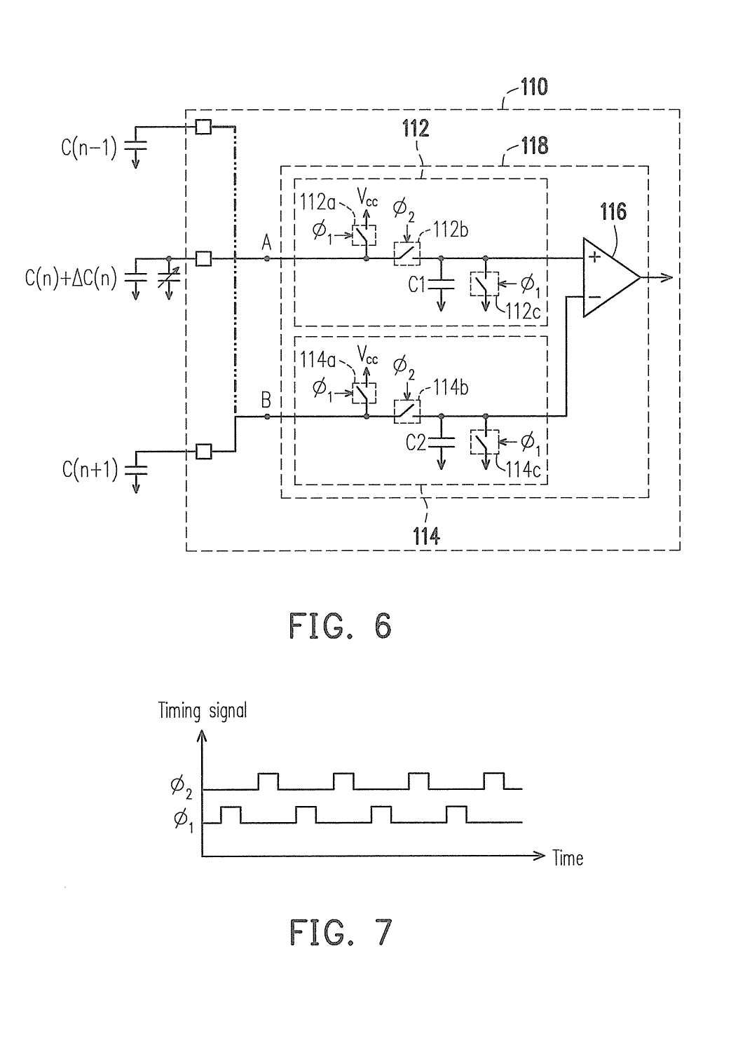

FIG. 6 is a schematic circuit diagram illustrating a capacitance sensing apparatus according to an embodiment of the invention. For the purpose of illustration, only the sensing capacitors C(n−1) and C(n+1), the capacitor under test C(n)+ΔC, and the differential sensing circuit 118 are illustrated in FIG. 6, while corresponding switch units are not shown therein. FIG. 7 illustrates a timing diagram when the capacitance sensing apparatus 110 depicted in FIG. 6 is operated.

As shown in FIG. 6 and FIG. 7, in the capacitance sensing apparatus 110 of this embodiment, the capacitance of the sensing capacitor C(n+1) serves as the reference capacitance for measuring the capacitance under test C(n)+ΔC. Besides, the charge-to-voltage converting circuits 112 and 114 have a charge redistribution structure as indicated in FIG. 6, for example; the difference comparing unit 116 is a comparator, for example.

During the operation of the capacitance sensing apparatus 110, switches 112a, 112c, 114a, and 114c of the charge-to-voltage converting circuits 112 and 114 are controlled by a timing signal ψ₁, and switches 112b and 114b of the charge-to-voltage converting circuits 112 and 114 are controlled by a timing signal ψ₂.

Hence, when the timing signal ψ₁ is at a high level, the switches 112a, 112c, 114a, and 114c are switched on, and a system voltage Vcc is applied to the sensing capacitor C(n+1) and the capacitor under test C(n)+ΔC. A storage capacitor C1 is in a discharge state. Here, charges respectively provided by the system voltage Vcc to the sensing capacitor C(n+1) and the capacitor under test C(n)+ΔC are Q1 and Q2, for example.

When the timing signal ψ₂ is at a high level, the switches 112b and 114b are switched on, such that the charge Q1 is redistributed among the capacitor under test C(n)+ΔC and the storage capacitor C1 when the switches 112b and 114b are controlled by the timing signal ψ₂. Hence, the voltage at a node A is Q1/[C(n)+ΔC+C1], and Q1=Vcc×[C(n)+ΔC]. Namely, the capacitance of the capacitor under test C(n)+ΔC is converted into the voltage under test by the charge-to-voltage converting circuit 112, and the voltage under test is input to a positive input end of the difference comparing unit 116.

On the other hand, similar to the charge-to-voltage converting circuit 112, the charge-to-voltage converting circuit 114 also converts the capacitance of the sensing capacitor C(n+1) into the reference voltage, and the reference voltage is input to a negative input end of the difference comparing unit 116. Hence, the voltage at a node B is Q2/[C(n+1)+C2], and Q2=Vcc×C(n+1).

After the operation of the timing signals ψ₁ and ψ₂ in the capacitance sensing apparatus 110, the difference comparing unit 116 compares the voltage under test and the reference voltage, obtains a difference therebetween, and outputs the difference to the back-end circuit. The touch position on the touch input interface is then determined.

In this embodiment, the difference comparing unit 116 is the comparator, for example, which should not be construed as a limitation to this invention. In another embodiment, the difference comparing unit 116 is a differential amplifier, for example. When the difference comparing unit 116 is the differential amplifier, the voltage difference between the voltage under test and the reference voltage can be compared, amplified, and output to the back-end circuit, so as to ensure accurate determination of the touch position. Besides, in still another embodiment, the difference comparing unit 116 can also be an integrator, for example. In this case, the voltage difference between the voltage under test and the reference voltage can be compared, integrated, and amplified by the integrator.

Moreover, in the capacitance sensing apparatus 110 of this embodiment, the capacitance of the sensing capacitor C(n+1) serves as the reference capacitance for measuring the capacitance under test C(n)+ΔC. According to another embodiment, in the capacitance sensing apparatus 110, the capacitance of the sensing capacitor C(n−1) can also serve as the reference capacitance for measuring the capacitance under test C(n)+ΔC. Here, the reference voltage received by the difference comparing unit 116 is Q2/[C(n−1)+C2], and Q2=Vcc×C(n−1). According to still another embodiment, in the capacitance sensing apparatus 110, the capacitances of the sensing capacitors C(n+1) and C(n−1) can also serve as the reference capacitances for measuring the capacitance under test C(n)+ΔC. Here, the reference voltage received by the difference comparing unit 116 is:

Q2/[(C(n+1)+C(n−1))/2+C2],

and Q2=Vcc×[C(n+1)+C(n−1)]/2.

Accordingly, in the embodiments of the invention, the capacitance sensing apparatus can control the switch units, such that the reference input end of the differential sensing circuit receives the reference capacitance provided by at least one of the sensing capacitors. The reference capacitance acts as a reference for measuring the capacitance under test. Thereby, the capacitance sensing apparatus is capable of adjusting reference capacitances of the capacitors under test, such that measured results are accurate, and that efficiency of measurement is further improved.

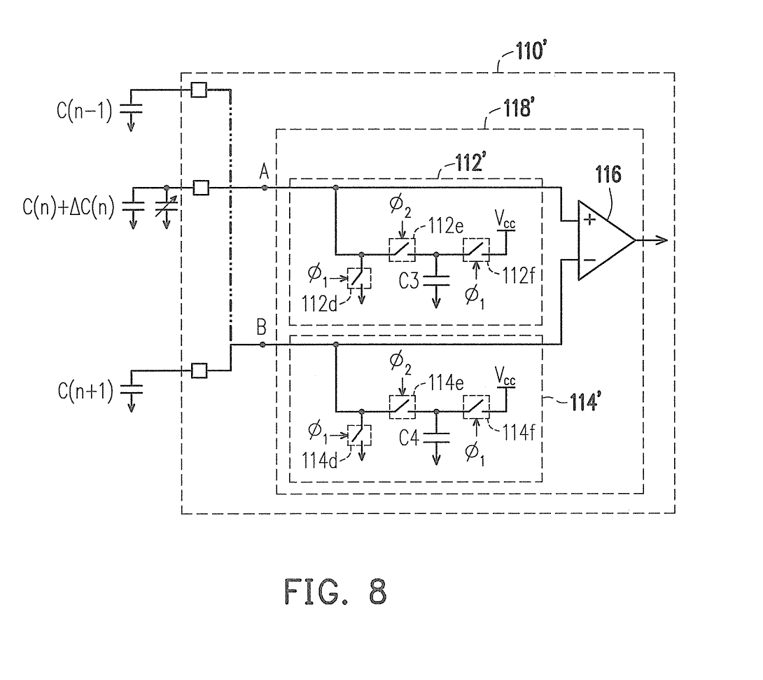

FIG. 8 is another schematic circuit diagram illustrating the capacitance sensing apparatus depicted in FIG. 3. Similarly, for the purpose of illustration, only the sensing capacitors C(n−1) and C(n+1), the capacitor under test C(n)+AC, and the differential sensing circuit 118 are illustrated in FIG. 8, while corresponding switch units are not shown therein. FIG. 7 illustrates the timing diagram when the capacitance sensing apparatus 110 depicted in FIG. 8 is operated.

As shown in FIG. 7 and FIG. 8, in the capacitance sensing apparatus 110 of this embodiment, the capacitance of the sensing capacitor C(n+1) serves as the reference capacitance for measuring the capacitance under test C(n)+ΔC. The charge-to-voltage converting circuits 112′ and 114′ have a charge redistribution structure as indicated in FIG. 8, for example; the difference comparing unit 116 is a comparator, for example. Here, the main difference between the capacitance sensing apparatus 110′ depicted in FIG. 8 and the capacitance sensing apparatus 110 depicted in FIG. 6 lies in that the charge redistribution structures of the charge-to-voltage converting circuits in the two apparatuses 110′ and 110 are different.

During the operation of the capacitance sensing apparatus 110′ of this embodiment, switches 112d, 112f, 114d, and 114f of the charge-to-voltage converting circuits 112′ and 114′ are controlled by a timing signal ψ₁, and switches 112e and 114e of the charge-to-voltage converting circuits 112′ and 114′ are controlled by a timing signal ψ₂.

Hence, when the timing signal ψ₁ is at a high level, the switches 112d, 112f, 114d, and 114f are switched on, and the system voltage Vcc is applied to storage capacitors C3 and C4 in the charge-to-voltage converting circuits 112′ and 114′. Here, the sensing capacitor C(n+1) and the capacitor under test C(n)+ΔC are in a discharge state. According to this embodiment, the storage capacitors C3 and C4 are assumed to have equal capacitance Ci, which is however not limited in this invention. Here, a charge supplied by the system voltage Vcc to the storage capacitors C3 and C4 is Qi, for example.

When the timing signal ψ₂ is at a high level, the switches 112e and 114e are switched on, such that the charge Qi is redistributed among the capacitors under test C(n)+ΔC and the storage capacitor Ci, i.e. C3 or C4, when the switches 112e and 114e are controlled by the timing signal ψ₂. Hence, the voltage at the node A is Q1/[C(n)+Δ+Ci], and Qi=Vcc×Ci. Namely, the capacitance of the capacitor under test C(n)+ΔC is converted into the voltage under test by the charge-to-voltage converting circuit 112′, and the voltage under test is input to the positive input end of the difference comparing unit 116.

On the other hand, similar to the charge-to-voltage converting circuit 112′, the charge-to-voltage converting circuit 114′ converts the capacitance of the sensing capacitor C(n+1) which acts as the reference capacitance into the reference voltage, and the reference voltage is input to the negative input end of the difference comparing unit 116. Hence, the voltage at the node B is Qi/[C(n+1)+Ci], and Qi=Vcc×Ci.

After the operation of the timing signals ψ₁ and ψ₂ in the capacitance sensing apparatus 110′, the difference comparing unit 116 compares the voltage under test and the reference voltage, obtains a difference therebetween, and outputs the difference to the back-end circuit. The touch position on the touch input interface is then determined.

In this embodiment, the difference comparing unit 116 is the comparator, for example, which should not be construed as a limitation to this invention. In another embodiment, the difference comparing unit 116 is a differential amplifier, for example. When the difference comparing unit 116 is the differential amplifier, the voltage difference between the voltage under test and the reference voltage can be compared, amplified, and output to the back-end circuit, so as to ensure accurate determination of the touch position. Besides, in still another embodiment, the difference comparing unit 116 can also be an integrator, for example. In this case, the voltage difference between the voltage under test and the reference voltage can be compared, integrated, and amplified by the integrator.

Moreover, in the capacitance sensing apparatus 110′ of this embodiment, the capacitance of the sensing capacitor C(n+1) serves as the reference capacitance for measuring the capacitance under test C(n)+ΔC. According to another embodiment, in the capacitance sensing apparatus 110′, the capacitance of the sensing capacitor C(n−1) can also serve as the reference capacitance for measuring the capacitance under test C(n)+ΔC. Here, the reference voltage received by the difference comparing unit 116 is Qi/[C(n−1)+Ci], and Qi=Vcc×Ci. According to still another embodiment, in the capacitance sensing apparatus 110′, the capacitances of the sensing capacitors C(n+1) and C(n−1) can also serve as the reference capacitances for measuring the capacitance under test C(n)+ΔC. Here, the reference voltage received by the difference comparing unit 116 is Qi/[(C(n+1)+C(n−1))/2+Ci], and Qi=Vcc×Ci.

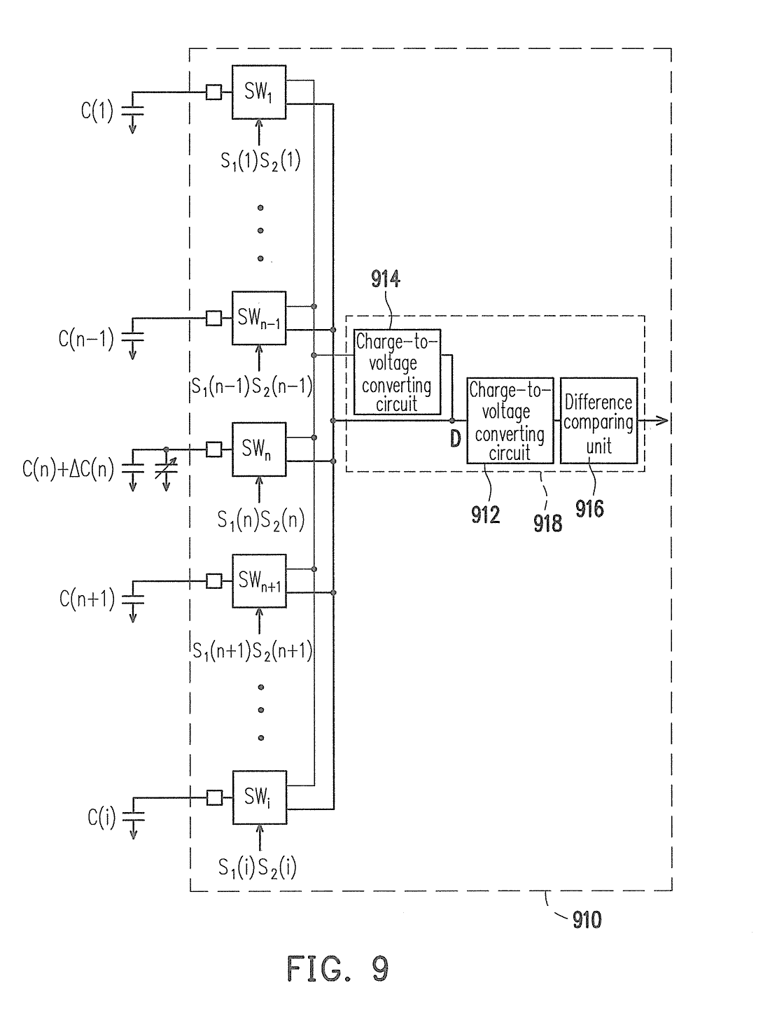

FIG. 9 is a block circuit diagram illustrating a capacitance sensing apparatus according to an embodiment of the invention. As shown in FIG. 9, the difference between the capacitance sensing apparatus 910 of this embodiment and the capacitance sensing apparatus 110 depicted in FIG. 2A rests in that a differential sensing circuit 918 of the capacitance sensing apparatus 910 includes a charge-to-voltage converting circuit 912, a charge polarity reversing circuit 914, and a difference comparing unit 916, for example.

In this embodiment, the charge polarity reversing circuit 914 receives a charge under test corresponding to the capacitance under test C(n)+ΔC and outputs the charge under test to the charge-to-voltage converting circuit 912 after polarity of the charge under test is reversed. The charge-to-voltage converting circuit 912 receives a reference charge corresponding to the reference capacitance and the charge under test of which the polarity is reversed. Here, the charge under test of which the polarity is reversed and the reference charge have opposite polarity.

Based on the above, the charge under test of which the polarity is reversed and the reference charge are offset at a node D, and a second difference between the charge under test and the reference charge is obtained. In this embodiment, the second difference is a charge difference. The charge-to-voltage converting circuit 912 converts the charge difference into the voltage difference and inputs the voltage difference to the difference comparing unit 916.

In this embodiment, the difference comparing unit 916 is an integrator, for example, which should not be construed as a limitation to this invention. The voltage difference is output to the back-end circuit after the voltage difference is integrated and amplified by the difference comparing unit 916, and thereby the touch position on the touch input interface is determined.

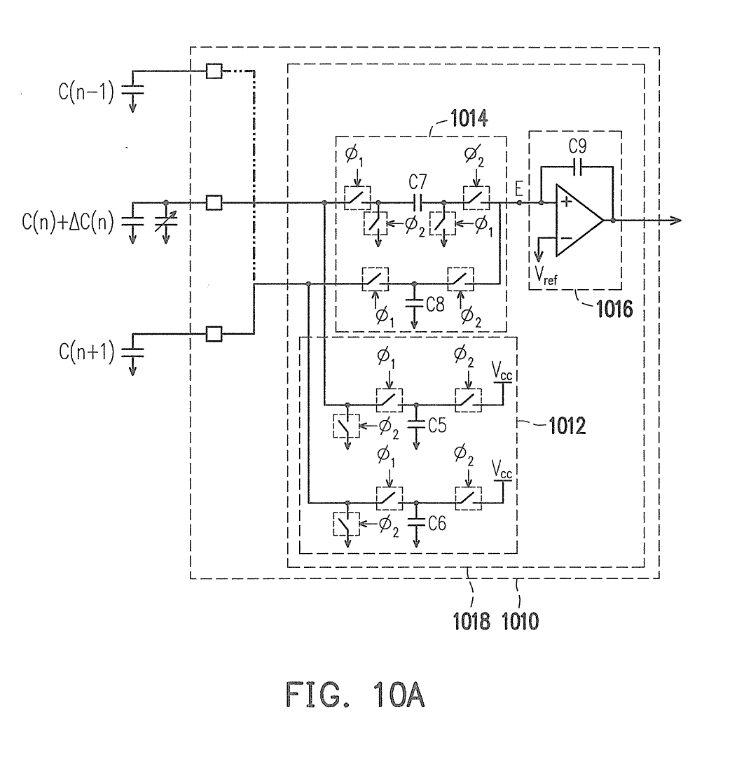

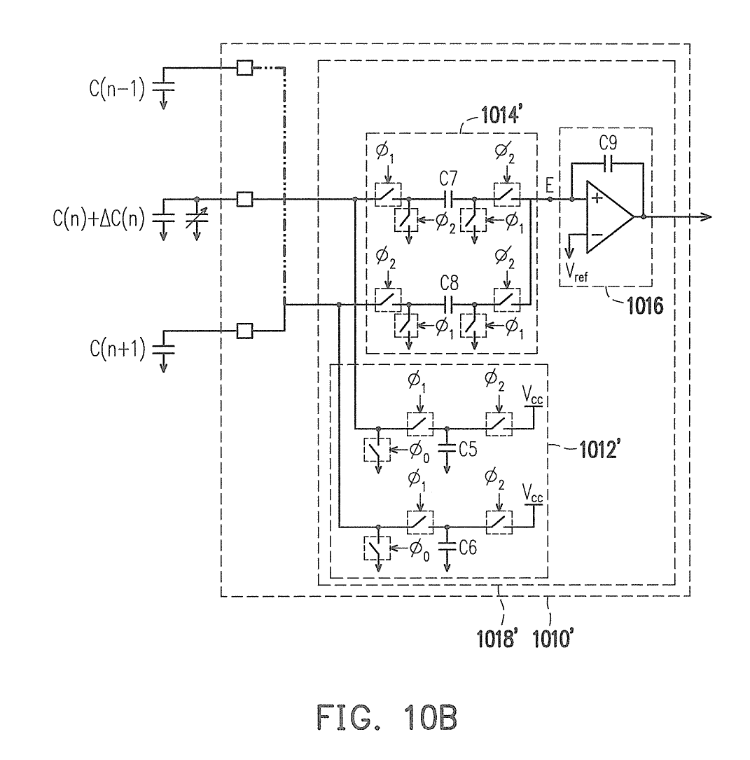

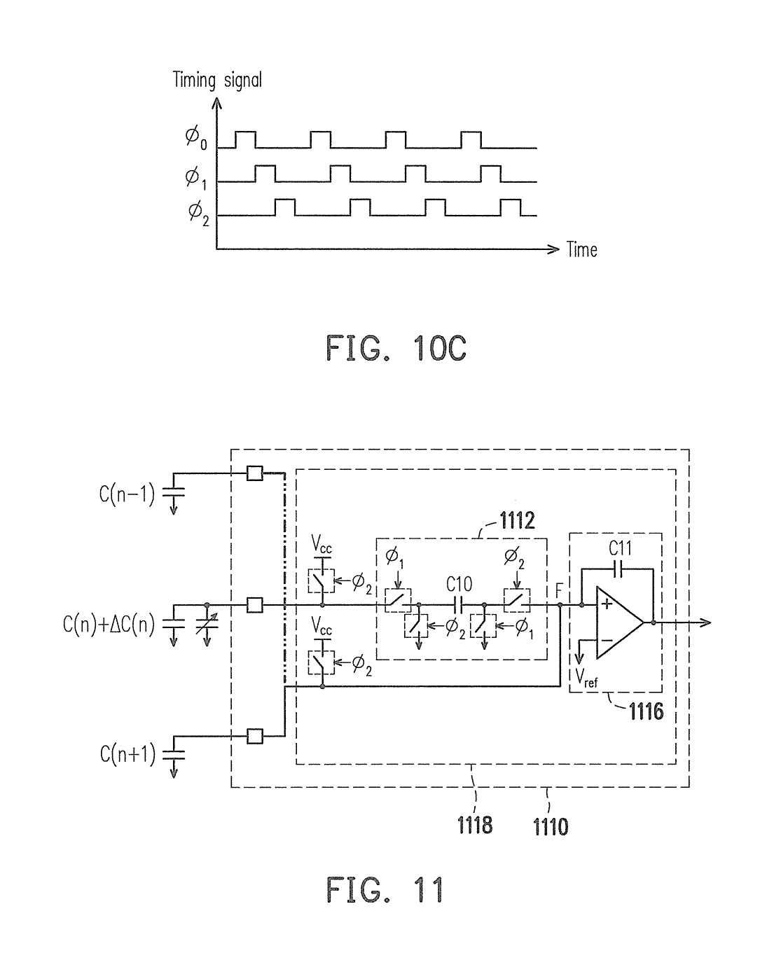

FIG. 10A is a schematic circuit diagram illustrating a capacitance sensing apparatus according to another embodiment of the invention. As indicated in FIG. 10A, the capacitance sensing apparatus 1010 is applied to a self capacitance touch sensing system in this embodiment but is applicable to other types of touch sensing systems according to this invention. According to this embodiment, the differential sensing circuit 1018 includes a charge-to-voltage converting circuit 1012, a charge polarity reversing circuit 1014, and a difference comparing unit 1016.

For the purpose of illustration, only the sensing capacitors C(n−1) and C(n+1), the capacitor under test C(n)+ΔC, and the differential sensing circuit 1018 are illustrated in FIG. 10A, while corresponding switch units are not shown therein. FIG. 7 illustrates a timing diagram when the capacitance sensing apparatus 1010 depicted in FIG. 10A is operated.

As shown in FIG. 7 and FIG. 10A, in the capacitance sensing apparatus 1010 of this embodiment, the capacitance of the sensing capacitor C(n+1) serves as the reference capacitance for measuring the capacitance under test C(n)+ΔC, which should not be construed as a limitation to this invention.

When the timing signal ψ₁ is at a high level, the charge stored in the capacitor under test C(n)+ΔC is redistributed among the capacitor under test C(n)+ΔC and the capacitors C5 and C7, and the charge stored in the reference capacitor C(n+1) is redistributed among the reference capacitors C(n+1) and the capacitors C6 and C8. When the timing signal ψ2 is at a high level, polarity of the charge under test stored in the capacitor C7 at the sensing input end is reversed, and a node E is provided. For instance, positive polarity of the redistributed charge under test is reversed into negative polarity by the capacitor C7, such that the charge under test with the reversed polarity can be supplied to the node E. Meanwhile, at the reference input end, the reference charge stored in the capacitor C8 is directly supplied to the node E, and polarity of the reference charge is not reversed. Hence, the charge under test of which the polarity is reversed and the reference charge have opposite polarity and are offset at the node E, and a charge difference between the charge under test and the reference charge is obtained. The charge-to-voltage converting circuit 1012 converts the charge difference into the voltage difference and inputs the voltage difference to the difference comparing unit 1016.

After the operation of the timing signals ψ₁ and ψ₂ in the capacitance sensing apparatus 1010, the difference comparing unit 1016 receives the voltage difference from the positive input end of the difference comparing unit 1016, integrates and amplifies the voltage difference, and outputs the voltage difference to the back-end circuit. Thereby, the touch position on the touch input interface can be determined.

In this embodiment, the difference comparing unit 1016 is an integrator, for example, which should not be construed as a limitation to this invention. In another embodiment, the difference comparing unit 1016 is a differential amplifier or a comparator, for example.

Moreover, in the capacitance sensing apparatus 1010 of this embodiment, the capacitance of the sensing capacitor C(n+1) serves as the reference capacitance for measuring the capacitance under test C(n)+ΔC. According to another embodiment, in the capacitance sensing apparatus 1010, the capacitance of the sensing capacitor C(n−1) can also serve as the reference capacitance for measuring the capacitance under test C(n)+ΔC. According to still another embodiment, in the capacitance sensing apparatus 1010, the capacitances of the sensing capacitors C(n+1) and C(n−1) can also serve as the reference capacitances for measuring the capacitance under test C(n)+ΔC.

Additionally, in the capacitance sensing apparatus 1010 of this embodiment, the polarity of the charge under test is reversed, and the charge under test and the reference charge are offset to obtain the charge difference, which should not be construed as a limitation to this invention. In another embodiment, the capacitance sensing apparatus 1010 can also reverse the polarity of the reference charge and offset the reference charge and the charge under test, so as to obtain a charge difference. The charge difference is converted into the voltage difference by the charge-to-voltage converting circuit. The voltage difference is integrated, amplified, and output to the back-end circuit by the difference comparing unit 1016, so as to determine the touch position on the touch input interface.

FIG. 10B is a schematic circuit diagram illustrating a capacitance sensing apparatus according to another embodiment of the invention. As indicated in FIG. 10B, the capacitance sensing apparatus 1010′ is applied to a self capacitance touch sensing system in this embodiment but is applicable to other types of touch sensing systems according to this invention. The difference between the capacitance sensing apparatus 1010′ of this embodiment and the capacitance sensing apparatus 1010 depicted in FIG. 10A rests in the circuit structures of a charge-to-voltage converting circuit 1012′ and a charge polarity reversing circuit 1014′.

For the purpose of illustration, only the sensing capacitors C(n−1) and C(n+1), the capacitor under test C(n)+ΔC, and the differential sensing circuit 1018′ are illustrated in FIG. 10B, while corresponding switch units are not shown therein. FIG. 10C illustrates a timing diagram when the capacitance sensing apparatus 1010′ depicted in FIG. 10B is operated. In this embodiment, a period during which the switches are controlled by every two of the timing signals ψ0 is, for example, a sensing period.

As shown in FIG. 10B and FIG. 10C, in the capacitance sensing apparatus 1010′ of this embodiment, the capacitance of the sensing capacitor C(n+1) serves as the reference capacitance for measuring the capacitance under test C(n)+ΔC, which should not be construed as a limitation to this invention.

When the timing signal ψ₀ is at a high level, the capacitor under test C(n)+ΔC and the reference capacitor C(n+1) are grounded via the charge-to-voltage converting circuit 1012′. That is to say, charges stored in the capacitor under test C(n)+ΔC and the reference capacitor C(n+1) are discharged by the switch corresponding to the timing signal ψ₀ via the charge-to-voltage converting circuit 1012′, so as to remove the charges stored in the capacitor under test C(n)+ΔC and the reference capacitor C(n+1) in the previous sensing period.

When the timing signal ψ₁ is at a high level, the charge stored in the capacitor under test C(n)+ΔC is redistributed among the under test capacitor C(n)+ΔC and the capacitors C5 and C7, and the charge stored in the reference capacitor C(n+1) is redistributed between the reference capacitor C(n+1) and the capacitor C6. When the timing signal ψ₂ is at a high level, polarity of the charge under test stored in the capacitor C7 at the sensing input end is reversed, and a node E is provided. For instance, positive polarity of the redistributed charge under test is reversed into negative polarity by the capacitor C7, such that the charge under test with the reversed polarity can be supplied to the node E. Meanwhile, at the reference input end, the charge stored in the reference capacitor C(n+1) is transmitted to and stored in the capacitor C8, and polarity of the reference charge is not reversed but directly supplied to the node E. Hence, the charge under test of which the polarity is reversed and the reference charge have opposite polarity and are offset at the node E, and a charge difference between the charge under test and the reference charge is obtained. The charge-to-voltage converting circuit 1012′ converts the charge difference into the voltage difference and inputs the voltage difference to the difference comparing unit 1016. When the timing signal ψ₀ is at a high level, the capacitance sensing apparatus 1010′ operates in another sensing period.

After each operation of the timing signals ψ₁ and ψ₂ in the capacitance sensing apparatus 1010′, i.e. in each sensing period, the difference comparing unit 1016 receives the voltage difference from the positive input end of the difference comparing unit 1016, integrates and amplifies the voltage difference, and outputs the voltage difference to the back-end circuit. Thereby, the touch position on the touch input interface can be determined.

In this embodiment, the difference comparing unit 1016 is, for example, an integrator, which should not be construed as a limitation to this invention. In another embodiment, the difference comparing unit 1016 is a differential amplifier or a comparator, for example.

Moreover, in the capacitance sensing apparatus 1010′ of this embodiment, the capacitance of the sensing capacitor C(n+1) serves as the reference capacitance for measuring the capacitance of under test C(n)+ΔC. According to another embodiment, in the capacitance sensing apparatus 1010′, the capacitance of the sensing capacitor C(n−1) can also serve as the reference capacitance for measuring the capacitance under test C(n)+ΔC. According to still another embodiment, in the capacitance sensing apparatus 1010′, the capacitances of the sensing capacitors C(n+1) and C(n−1) can also serve as the reference capacitances for measuring the capacitance under test C(n)+ΔC.

Additionally, the capacitance sensing apparatus 1010′ of this embodiment reverses the polarity of the charge under test and offsets the charge under test and the reference charge to obtain the charge difference, which should not be construed as a limitation to this invention. In another embodiment, the capacitance sensing apparatus 1010′ can also reverse the polarity of the reference charge and offset the reference charge and the charge under test, so as to obtain a charge difference. The charge difference is converted into the voltage difference by the charge-to-voltage converting circuit 1012′. The voltage difference is integrated and amplified by the difference comparing unit 1016 and output to the back-end circuit, so as to determine the touch position on the touch input interface.

FIG. 11 is a schematic circuit diagram illustrating a capacitance sensing apparatus according to an embodiment of the invention. As indicated in FIG. 11, in this embodiment of the invention, a differential sensing circuit 1118 of the capacitance sensing apparatus 1110 includes a charge polarity reversing circuit 1112 and a difference comparing unit 1116. Here, the difference comparing unit 1116 is an integrator, for example.

For the purpose of illustration, only the sensing capacitors C(n−1) and C(n+1), the capacitor under test C(n)+ΔC, and the differential sensing circuit 1118 are illustrated in FIG. 11, while corresponding switch units are not shown therein. FIG. 7 illustrates a timing diagram when the capacitance sensing apparatus 1110 depicted in FIG. 11 is operated.

As shown in FIG. 7 and FIG. 11, in the capacitance sensing apparatus 1110 of this embodiment, the capacitance of the sensing capacitor C(n+1) serves as the reference capacitance for measuring the capacitance under test C(n)+ΔC, which should not be construed as a limitation to this invention.

When the timing signal ψ₂ is at a high level, the system voltage Vcc is applied to the capacitor under test C(n)+ΔC and the reference capacitor C(n+1). When the timing signal ψ₁ is at a high level, the charge stored in the capacitor under test is redistributed between the capacitor under test C(n)+ΔC and the capacitor C10 when the switches are controlled by the timing signal ψ₁. The capacitor C10 reverses the polarity of the redistributed charge under test, such that the charge under test with the reversed polarity is obtained at a node F when the timing signal ψ₂ is again at the high level. On the other hand, the charge stored in the reference capacitor is supplied to the node F and serves as the reference charge. Hence, the charge under test of which the polarity is reversed and the reference charge are offset at the node F, and a charge difference between the charge under test and the reference charge is obtained.

After the operation of the timing signals ψ₁ and ψ₂ in the capacitance sensing apparatus 1110, the difference comparing unit 1116 receives the charge difference from the positive input end of the difference comparing unit 1116, accumulates and amplifies the charge difference, and outputs the charge difference to the back-end circuit. Thereby, the touch position on the touch input interface can be determined.

In this embodiment, the difference comparing unit 1116 is, for example, an integrator, which should not be construed as a limitation to this invention. In another embodiment, the difference comparing unit 1116 is a differential amplifier or a comparator, for example.

Moreover, in the capacitance sensing apparatus 1110 of this embodiment, the capacitance of the sensing capacitor C(n+1) serves as the reference capacitance for measuring the capacitance under test C(n)+ΔC. According to another embodiment, in the capacitance sensing apparatus 1110, the capacitance of the sensing capacitor C(n−1) can also serve as the reference capacitance for measuring the capacitance under test C(n)+ΔC. According to still another embodiment, in the capacitance sensing apparatus 1110, the capacitances of the sensing capacitors C(n+1) and C(n−1) can also serve as the reference capacitances for measuring the capacitance under test C(n)+ΔC.

Additionally, the capacitance sensing apparatus 1110 of this embodiment reverses the polarity of the charge under test and offsets the charge under test and the reference charge to obtain the charge difference, which should not be construed as a limitation to this invention. In another embodiment, the capacitance sensing apparatus 1110 can also reverse the polarity of the reference charge and offset the reference charge and the charge under test to obtain the charge difference. The voltage difference is output to the back-end circuit after the charge difference is integrated, amplified, and converted into the voltage difference by the difference comparing unit 1116, and thereby the touch position on the touch input interface is determined.

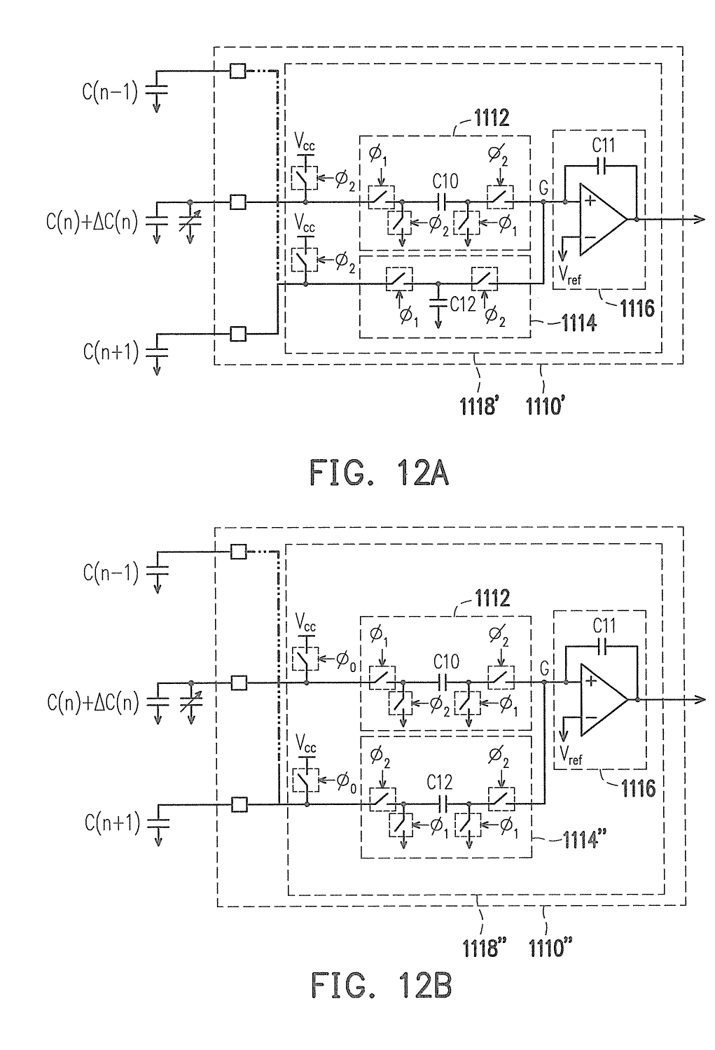

FIG. 12A is a schematic circuit diagram illustrating a capacitance sensing apparatus according to an embodiment of the invention. The difference between the capacitance sensing apparatus 1110′ of this embodiment as shown in FIG. 12A and the capacitance sensing apparatus 1110 depicted in FIG. 11 lies in that a differential sensing circuit 1118′ of the capacitance sensing apparatus 1110′ further includes a charge polarity non-reversing circuit 1114, for example.

For the purpose of illustration, only the sensing capacitors C(n−1) and C(n+1), the capacitor under test C(n)+ΔC, and the differential sensing circuit 1118′ are illustrated in FIG. 12A, while corresponding switch units are not shown therein. FIG. 7 illustrates timing diagram when the capacitance sensing apparatus 1110′ depicted in FIG. 12A is operated.

As shown in FIG. 7 and FIG. 12A, in the capacitance sensing apparatus 1110′ of this embodiment, the capacitance of the sensing capacitor C(n+1) serves as the reference capacitance for measuring the capacitance under test C(n)+ΔC, which should not be construed as a limitation to this invention.

When the timing signal ψ₂ is at a high level, the system voltage Vcc is applied to the capacitor under test C(n)+ΔC and the reference capacitor C(n+1). When the timing signal ψ₁ is at a high level, the charge stored in the capacitor under test is redistributed between the capacitor under test C(n)+ΔC and the capacitor C10 when the switches are controlled by the timing signal ψ₁. Polarity of the redistributed charge under test is reversed by the capacitor C10, such that the charge under test with the reversed polarity can be supplied to the node G. Meanwhile, the charge stored in the reference capacitor is redistributed between the capacitors C(n+1) and C12 when the switches are controlled by the timing signal ψ1.

Note that the capacitor C12 in this embodiment does not reverse polarity of the reference charge but directly provides a node G with the reference charge when the timing signal ψ₂ is at the high level. Hence, the charge under test of which the polarity is reversed and the reference charge are offset at the node G when the timing signal ψ₂ is again at the high level, and a charge difference between the charge under test and the reference charge is obtained.

After the operation of the timing signals ψ₁ and ψ₂ in the capacitance sensing apparatus 1110′, the difference comparing unit 1116 receives the charge difference from the positive input end of the difference comparing unit 1116, accumulates and amplifies the charge difference, and outputs the charge difference to the back-end circuit. Thereby, the touch position on the touch input interface can be determined.

In this embodiment, the difference comparing unit 1116 is, for example, an integrator, which should not be construed as a limitation to this invention. In another embodiment, the difference comparing unit 1116 is a differential amplifier or a comparator, for example.

Moreover, in the capacitance sensing apparatus 1110′ of this embodiment, the capacitance of the sensing capacitor C(n+1) serves as the reference capacitance for measuring the capacitance under test C(n)+ΔC. According to another embodiment, in the capacitance sensing apparatus 1110′, the capacitance of the sensing capacitor C(n−1) can also serve as the reference capacitance for measuring the capacitance under test C(n)+ΔC. According to still another embodiment, in the capacitance sensing apparatus 1110′, the capacitances of the sensing capacitors C(n+1) and C(n−1) can also serve as the reference capacitances for measuring the capacitance under test C(n)+ΔC.

Additionally, the capacitance sensing apparatus 1110′ of this embodiment reverses the polarity of the charge under test and offsets the charge under test and the reference charge to obtain the charge difference, which should not be construed as a limitation to this invention. In another embodiment, the capacitance sensing apparatus 1110′ can also reverse the polarity of the reference charge and offset the reference charge and the charge under test to obtain the charge difference. The voltage difference is output to the back-end circuit after the charge difference is integrated, amplified, and converted into the voltage difference by the difference comparing unit 1116, and thereby the touch position on the touch input interface is determined.

FIG. 12B is a schematic circuit diagram illustrating a capacitance sensing apparatus according to an embodiment of the invention. The difference between a capacitance sensing apparatus 1110″ of this embodiment as shown in FIG. 12B and the capacitance sensing apparatus 1110′ depicted in FIG. 12A lies in the circuit structure of a charge polarity non-reversing circuit 1114″, for example.

For the purpose of illustration, only the sensing capacitors C(n−1) and C(n+1), the capacitor under test C(n)+ΔC, and the differential sensing circuit 1118″ are illustrated in FIG. 12B, while corresponding switch units are not shown therein. FIG. 10C illustrates time-pulse waveforms when the capacitance sensing apparatus 1110″ depicted in FIG. 12B is operated. In this embodiment, the period during which the switches are controlled by every two of the timing signals ψ₀ is, for example, a sensing period.

As shown in FIG. 10C and FIG. 12B, in the capacitance sensing apparatus 1110″ of this embodiment, the capacitance of the sensing capacitor C(n+1) serves as the reference capacitance for measuring the capacitance under test C(n)+ΔC, which should not be construed as a limitation to this invention.

When the timing signal ψ₀ is at a high level, the system voltage Vcc is applied to the capacitor under test C(n)+ΔC and the reference capacitor C(n+1). When the timing signal ψ₁ is at a high level, the charge stored in the capacitor under test is redistributed between the capacitor under test C(n)+ΔC and the capacitor C10 when the switches are controlled by the timing signal ψ₁. When the timing signal ψ₂ is at a high level, polarity of the redistributed charge under test is reversed by the capacitor C10, such that the charge under test with the reversed polarity can be supplied to the node G3. Meanwhile, the charge stored in the reference capacitor is redistributed between the capacitors C(n+1) and C12 when the switches are controlled by the timing signal ψ₂.

Note that the capacitor C12 in this embodiment does not reverse polarity of the reference charge but directly provides the node G with the reference charge when the timing signal ψ₂ is at the high level. Hence, the charge under test of which the polarity is reversed and the reference charge are offset at the node G when the timing signal ψ₂ is at the high level, and a charge difference between the charge under test and the reference charge is obtained.

After each operation of the timing signals ψ₁ and ψ₂ in the capacitance sensing apparatus 1110″, i.e. in each sensing period, the difference comparing unit 1116 receives the charge difference from the positive input end of the difference comparing unit 1016, integrates and amplifies the charge difference, and outputs the charge difference to the back-end circuit. Thereby, the touch position on the touch input interface can be determined.

In this embodiment, the difference comparing unit 1116 is, for example, an integrator, which should not be construed as a limitation to this invention. In another embodiment, the difference comparing unit 1116 is a differential amplifier or a comparator, for example.

Moreover, in the capacitance sensing apparatus 1110″ of this embodiment, the capacitance of the sensing capacitor C(n+1) serves as the reference capacitance for measuring the capacitance of under test C(n)+ΔC. According to another embodiment, in the capacitance sensing apparatus 1110″, the capacitance of the sensing capacitor C(n−1) can also serve as the reference capacitance for measuring the capacitance under test C(n)+ΔC. According to still another embodiment, in the capacitance sensing apparatus 1110″, the capacitances of the sensing capacitors C(n+1) and C(n−1) can both serve as the reference capacitances for measuring the capacitance under test C(n)+ΔC.

Additionally, the capacitance sensing apparatus 1110″ of this embodiment reverses the polarity of the charge under test and offsets the charge under test and the reference charge to obtain the charge difference, which should not be construed as a limitation to this invention. In another embodiment, the capacitance sensing apparatus 1110″ can also reverse the polarity of the reference charge and offset the reference charge and the charge under test to obtain a charge difference. The voltage difference is output to the back-end circuit after the charge difference is integrated, amplified, and converted into the voltage difference by the difference comparing unit 1116, and thereby the touch position on the touch input interface is determined.

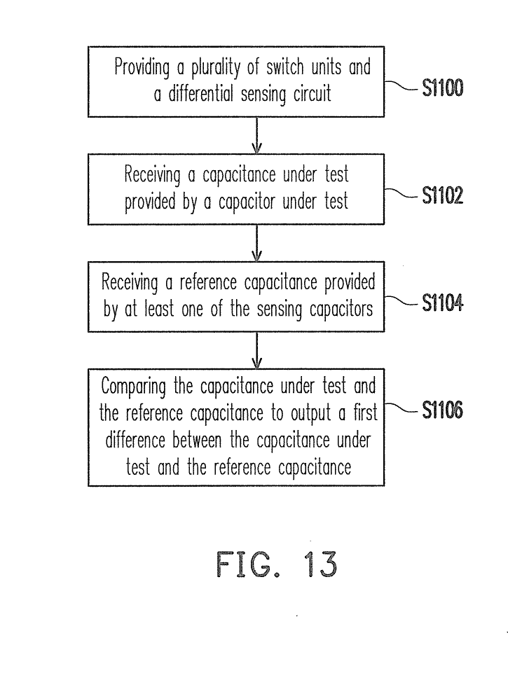

FIG. 13 is a flowchart of a capacitance sensing method according to an embodiment of the invention. With reference to FIG. 2A and FIG. 13, the capacitance sensing method of this embodiment includes following steps. In step S1100, a plurality of switch units SW₁˜SWᵢ and a differential sensing circuit 118 are provided. Each of the switch units SW₁˜SWᵢ is coupled to a corresponding sensing capacitor. In step S1102, a capacitance under test provided by at least one of the capacitors under test (e.g. the capacitor under test C(n)+ΔC) is received. In step S1104, a reference capacitance provided by at least one of the sensing capacitors is received. For instance, the reference capacitance provided by the sensing capacitor C(n−1) or C(n+1) is received. In step S1106, the differential sensing circuit compares the capacitance under test and the reference capacitance to output a first difference between the capacitance under test and the reference capacitance.

Besides, the capacitance sensing method described in this embodiment of the invention is sufficiently taught, suggested, and embodied in the embodiments illustrated in FIG. 1 to FIG. 12A, and therefore no further description is provided herein.

In light of the foregoing, according to the embodiments of the invention, the capacitance sensing apparatus can control the switch units, such that the reference input end of the differential sensing circuit receives the reference capacitance provided by at least one of the sensing capacitors. The reference capacitance acts as a reference for measuring the capacitance under test. Thereby, the capacitance sensing apparatus is capable of adjusting reference capacitances of the capacitors under test, such that measured results are accurate, and that efficiency of measurement is further improved.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A capacitance sensing apparatus comprising:
a plurality of switch units, each of the switch units having a first end, a second end, and a third end, the third end of each of the switch units being coupled to a corresponding sensing capacitor; and
a differential sensing circuit having a sensing input end, a reference input end, and an output end, the sensing input end being coupled to the first end of each of the switch units to receive a capacitance under test provided by at least one of the sensing capacitors, the reference input end being coupled to the second end of each of the switch units to receive a reference capacitance provided by at least one of the sensing capacitors,
wherein the differential sensing circuit compares the capacitance under test and the reference capacitance to output a first difference between the capacitance under test and the reference capacitance through the output end of the differential sensing circuit.

2. The capacitance sensing apparatus as claimed in claim 1, each of the switch units comprising:
a first switch having a first end and a second end, the first end of the first switch being coupled to a corresponding one of the sensing capacitors, the second end of the first switch being coupled to the sensing input end of the differential sensing circuit; and
a second switch having a first end and a second end, the first end of the second switch being coupled to the first end of the first switch, the second end of the second switch being coupled to the reference input end of the differential sensing circuit.

3. The capacitance sensing apparatus as claimed in claim 1, the differential sensing circuit comprising:
a first charge-to-voltage converting circuit coupled to the first end of each of the switch units to receive the capacitance under test, the first charge-to-voltage converting circuit converting the capacitance under test into a voltage under test;
a second charge-to-voltage converting circuit coupled to the second end of each of the switch units to receive the reference capacitance, the second charge-to-voltage converting circuit converting the reference capacitance into a reference voltage; and
a difference comparing unit having a first input end, a second input end, and an output end, the first input end being coupled to the first charge-to-voltage converting circuit to receive the voltage under test, the second input end being coupled to the second charge-to-voltage converting circuit to receive the reference voltage,
wherein the difference comparing unit compares the voltage under test and the reference voltage to output the first difference through the output end of the difference comparing unit.

4. The capacitance sensing apparatus as claimed in claim 1, the differential sensing circuit comprising:
a charge polarity reversing circuit coupled to the second end of each of the switch units to receive a reference charge corresponding to the reference capacitance and reverse polarity of the reference charge;
a charge-to-voltage converting circuit coupled to the first end of each of the switch units to receive a charge under test corresponding to the capacitance under test and receive the reference charge of which the polarity is reversed, wherein polarity of the charge under test is different from the polarity of the reference charge, a second difference between the charge under test and the reference charge is obtained, and the charge-to-voltage converting circuit converts the second difference into the first difference; and
a difference comparing unit coupled to the charge-to-voltage converting circuit to receive the first difference, wherein the difference comparing unit amplifies and outputs the first difference.

5. The capacitance sensing apparatus as claimed in claim 1, the differential sensing circuit comprising:
a charge polarity reversing circuit coupled to the first end of each of the switch units to receive a charge under test corresponding to the capacitance under test and reverse polarity of the charge under test;
a charge-to-voltage converting circuit coupled to the second end of each of the switch units to receive a reference charge corresponding to the reference capacitance and receive the charge under test of which the polarity is reversed, wherein the polarity of the charge under test is different from polarity of the reference charge, a second difference between the charge under test and the reference charge is obtained, and the charge-to-voltage converting circuit converts the second difference into the first difference; and
a difference comparing unit coupled to the charge-to-voltage converting circuit to receive the first difference, wherein the difference comparing unit amplifies and outputs the first difference.

6. The capacitance sensing apparatus as claimed in claim 1, the differential sensing circuit comprising:
a charge polarity reversing circuit coupled to the first end of each of the switch units to receive a charge under test corresponding to the capacitance under test and reverse polarity of the charge under test; and
a difference comparing unit coupled to the second end of each of the switch units to receive a reference charge corresponding to the reference capacitance and receive the charge under test of which the polarity is reversed,
wherein the polarity of the charge under test is different from polarity of the reference charge, a second difference between the charge under test and the reference charge is obtained, and the difference comparing unit converts the second difference into the first difference and outputs the first difference.

7. The capacitance sensing apparatus as claimed in claim 6, the differential sensing circuit further comprising:
a charge polarity non-reversing circuit coupled between the difference comparing unit and the second end of each of the switch units.

8. The capacitance sensing apparatus as claimed in claim 1, the differential sensing circuit comprising:
a charge polarity reversing circuit coupled to the second end of each of the switch units to receive a reference charge corresponding to the reference capacitance and reverse polarity of the reference charge; and
a difference comparing unit coupled to the first end of each of the switch units to receive a charge under test corresponding to the capacitance under test and receive the reference charge of which the polarity is reversed,
wherein polarity of the charge under test is different from the polarity of the reference charge, a second difference between the charge under test and the reference charge is obtained, and the difference comparing unit converts the second difference into the first difference and outputs the first difference.

9. The capacitance sensing apparatus as claimed in claim 8, the differential sensing circuit further comprising:
a charge polarity non-reversing circuit coupled between the difference comparing unit and the first end of each of the switch units.

10. The capacitance sensing apparatus as claimed in claim 1, wherein the differential sensing circuit comprises a differential amplifier, a comparator, or an integrator.

11. A touch sensing system comprising:
a touch input interface comprising a plurality of sensing capacitors; and
at least one capacitance sensing apparatus comprising:
a plurality of switch units, each of the switch units having a first end, a second end, and a third end, the third end of each of the switch units being coupled to a corresponding one of the sensing capacitors; and
a differential sensing circuit having a sensing input end, a reference input end, and an output end, the sensing input end being coupled to the first end of each of the switch units to receive a capacitance under test provided by at least one of the sensing capacitors, the reference input end being coupled to the second end of each of the switch units to receive a reference capacitance provided by at least one of the sensing capacitors,
wherein the differential sensing circuit compares the capacitance under test and the reference capacitance to output a first difference between the capacitance under test and the reference capacitance through the output end of the differential sensing circuit.

12. The touch sensing system as claimed in claim 11, each of the switch units comprising:
a first switch having a first end and a second end, the first end of the first switch being coupled to a corresponding one of the sensing capacitors, the second end of the first switch being coupled to the sensing input end of the differential sensing circuit; and
a second switch having a first end and a second end, the first end of the second switch being coupled to the first end of the first switch, the second end of the second switch being coupled to the reference input end of the differential sensing circuit.

13. The touch sensing system as claimed in claim 11, the differential sensing circuit comprising:
a first charge-to-voltage converting circuit coupled to the first end of each of the switch units to receive the capacitance under test, the first charge-to-voltage converting circuit converting the capacitance under test into a voltage under test;
a second charge-to-voltage converting circuit coupled to the second end of each of the switch units to receive the reference capacitance, the second charge-to-voltage converting circuit converting the reference capacitance into a reference voltage; and
a difference comparing unit having a first input end, a second input end, and an output end, the first input end being coupled to the first charge-to-voltage converting circuit to receive the voltage under test, the second input end being coupled to the second charge-to-voltage converting circuit to receive the reference voltage,
wherein the difference comparing unit compares the voltage under test and the reference voltage to output the first difference through the output end of the difference comparing unit.

14. The touch sensing system as claimed in claim 11, the differential sensing circuit comprising:
a charge polarity reversing circuit coupled to the second end of each of the switch units to receive a reference charge corresponding to the reference capacitance and reverse polarity of the reference charge;
a charge-to-voltage converting circuit coupled to the first end of each of the switch units to receive a charge under test corresponding to the capacitance under test and receive the reference charge of which the polarity is reversed, wherein polarity of the charge under test is different from the polarity of the reference charge, a second difference between the charge under test and the reference charge is obtained, and the charge-to-voltage converting circuit converts the second difference into the first difference; and
a difference comparing unit coupled to the charge-to-voltage converting circuit to receive the first difference, wherein the difference comparing unit amplifies and outputs the first difference.

15. The touch sensing system as claimed in claim 11, the differential sensing circuit comprising:
a charge polarity reversing circuit coupled to the first end of each of the switch units to receive a charge under test corresponding to the capacitance under test and reverse polarity of the charge under test;
a charge-to-voltage converting circuit coupled to the second end of each of the switch units to receive a reference charge corresponding to the reference capacitance and receive the charge under test of which the polarity is reversed, wherein the polarity of the charge under test is different from polarity of the reference charge, a second difference between the charge under test and the reference charge is obtained, and the charge-to-voltage converting circuit converts the second difference into the first difference; and
a difference comparing unit coupled to the charge-to-voltage converting circuit to receive the first difference, wherein the difference comparing unit amplifies and outputs the first difference.

16. The touch sensing system as claimed in claim 11, the differential sensing circuit comprising:
a charge polarity reversing circuit coupled to the first end of each of the switch units to receive a charge under test corresponding to the capacitance under test and reverse polarity of the charge under test; and
a difference comparing unit coupled to the second end of each of the switch units to receive a reference charge corresponding to the reference capacitance and receive the charge under test of which the polarity is reversed,
wherein the polarity of the charge under test is different from polarity of the reference charge, a second difference between the charge under test and the reference charge is obtained, and the difference comparing unit converts the second difference into the first difference and outputs the first difference.

17. The touch sensing system as claimed in claim 16, the differential sensing circuit further comprising:
a charge polarity non-reversing circuit coupled between the difference comparing unit and the second end of each of the switch units.

18. The touch sensing system as claimed in claim 11, the differential sensing circuit comprising:
a charge polarity reversing circuit coupled to the second end of each of the switch units to receive a reference charge corresponding to the reference capacitance and reverse polarity of the reference charge; and
a difference comparing unit coupled to the first end of each of the switch units to receive a charge under test corresponding to the capacitance under test and receive the reference charge of which the polarity is reversed,
wherein polarity of the charge under test is different from the polarity of the reference charge, a second difference between the charge under test and the reference charge is obtained, and the difference comparing unit converts the second difference into the first difference and outputs the first difference.

19. The touch sensing system as claimed in claim 18, the differential sensing circuit further comprising:
a charge polarity non-reversing circuit coupled between the difference comparing unit and the first end of each of the switch units.

20. The touch sensing system as claimed in claim 11, wherein the differential sensing circuit comprises a differential amplifier, a comparator, or an integrator.

21. A capacitance sensing method comprising:
providing a plurality of switch units and a differential sensing circuit, wherein each of the switch units is coupled to a corresponding sensing capacitor;
receiving a capacitance under test provided by at least one of the sensing capacitors;
receiving a reference capacitance provided by at least one of the sensing capacitors; and
comparing the capacitance under test and the reference capacitance to obtain a first difference between the capacitance under test and the reference capacitance.

22. The capacitance sensing method as claimed in claim 21, further comprising:
converting the capacitance under test into a voltage under test after the capacitance under test is received; and
converting the reference capacitance into a reference voltage after the reference capacitance is received.

23. The capacitance sensing method as claimed in claim 22, in the step of comparing the capacitance under test and the reference capacitance, further comprising comparing the voltage under test and the reference voltage to generate the first difference.

24. The capacitance sensing method as claimed in claim 21, further comprising:
in the step of receiving the reference capacitance, receiving a reference charge corresponding to the reference capacitance and reversing polarity of the reference charge;
in the step of receiving the capacitance under test, receiving a charge under test corresponding to the capacitance under test, wherein polarity of the charge under test is different from the polarity of the reference charge.

25. The capacitance sensing method as claimed in claim 24, further comprising:
receiving the charge under test and the reference charge of which the polarity is reversed to obtain a second difference.

26. The capacitance sensing method as claimed in claim 25, in the step of comparing the capacitance under test and the reference capacitance, further comprising converting the second difference into the first difference to obtain the first difference between the capacitance under test and the reference capacitance.

27. The capacitance sensing method as claimed in claim 21, further comprising:
in the step of receiving the reference capacitance, receiving a reference charge corresponding to the reference capacitance;
in the step of receiving the capacitance under test, receiving a charge under test corresponding to the capacitance under test and reversing polarity of the charge under test, wherein the polarity of the charge under test is different from polarity of the reference charge.

28. The capacitance sensing method as claimed in claim 27, further comprising:
receiving the reference charge and the charge under test of which the polarity is reversed to obtain a second difference.

29. The capacitance sensing method as claimed in claim 28, in the step of comparing the capacitance under test and the reference capacitance, further comprising converting the second difference into the first difference to obtain the first difference between the capacitance under test and the reference capacitance.

30. The capacitance sensing method as claimed in claim 21, in the step of comparing the capacitance under test and the reference capacitance, further comprising obtaining the first difference through a differential amplifier, a comparator, or an integrator.
